(19) United States
(12) Patent Application Publication
(10) Pub. No.: US 2004/0239239 A1
(43) Pub. Date: Dec. 2, 2004

(54) Electroluminescent device and method for manufacturing the same

(75) Inventor: Akio Fukase, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/806,177

(22) Filed: Mar. 23, 2004

(30) Foreign Application Priority Data
Mar. 27, 2003 (JP) 2003-88062
Jan. 15, 2004 (JP) 2004-7906

(51) Int. Cl. H05B 33/00; H05B 33/02

(52) U.S. Cl. 313/506; 313/503; 313/504

(57) ABSTRACT

The invention provides a top-emitting electroluminescent device having excellent emission intensity achieved by improving the total transmittance of layers above a light-emitting layer, which include a transparent conductive film, and by enhancing electron injection efficiency. The top-emitting organic electroluminescent device can include a substrate, an electrode disposed on the substrate, a hole-injection layer disposed on the electrode, a light-emitting layer disposed on the hole-injection layer, a reduced layer disposed on the light-emitting layer, and a transparent conductive film disposed on the reduced layer. The reduced layer 5 can be formed by the reduction of an alkali metal or alkaline earth metal compound with a reductant, resulting in an improvement in the electron injection efficiency to the light-emitting layer 4.

### BACKGROUND OF THE INVENTION

1. Field of Invention

The present invention relates to electroluminescent devices and, particularly, to a so-called top-emitting electroluminescent device, which emits light from its top.

2. Description of Related Art

Electroluminescent (EL) devices are useful as light-emitting devices for display or illumination. In particular, organic EL devices, which can operate at low voltage, are expected to provide energy-saving displays or light-emitting devices. A typical organic EL device includes an organic layer sandwiched between two electrodes.

Conventionally, so-called bottom-emitting organic EL devices are often used. A bottom-emitting organic EL device emits light through a glass substrate on which thin-film transistors (TFTs) are formed (through the surface of the device adjacent to the glass substrate). However, a sophisticated organic EL device having a single substrate provided with additional circuitry requires a top-emission structure in which light exits through the top of the device formed on a glass substrate (through the surface of the device facing away from the glass substrate).

This structure allows light to exit the device without being blocked by, for example, a drive circuit formed on the glass substrate. This structure, therefore, can increase the aperture ratio of the device to realize high luminance and high definition.

A top-emitting organic EL device requires a transparent electrode at the top of the device. A typical top-emitting EL device includes an organic film, a thin electron-injection layer of a metal with a low work function on the organic film, and an indium tin oxide (ITO) layer deposited on the electron-injection layer. See, for example Japanese Unexamined Patent Application Publication No. 8-185984.

Specifically, this device includes an alkali metal or alkaline earth metal thin layer as the electron-injection layer to emit light from the top of the device (through its cathode). The electron-injection layer has the function of injecting carriers, namely electrons, into the organic film. It is difficult to use this electron-injection layer directly as an electrode due to its high resistance, which stems from its small thickness. Therefore, a transparent conductive film (a transparent electrode, made of, for example, ITO) having high transmittance is formed on the top of the electron-injection layer by sputtering.

### SUMMARY OF THE INVENTION

However, in the above process alkali metals and alkaline earth metals are readily oxidized due to their low work function. Therefore, the sputtering of ITO in an oxygen atmosphere oxidizes the alkali metal or alkaline earth metal layer, thus decreasing its electron injection efficiency and impairing the device characteristics.

To solve the above problems, the invention can provide a top-emitting electroluminescent device having excellent emission intensity achieved by improving the total transmittance of the layers above the light-emitting layer, such as the transparent conductive film, and by enhancing the electron injection efficiency.

An organic electroluminescent device of the invention can include a substrate, an electrode disposed on the substrate, a hole-injection layer disposed on the electrode, a light-emitting layer disposed on the hole-injection layer, a reduced layer disposed on the light-emitting layer, and a transparent conductive film disposed on the reduced layer. The reduced layer is formed by the reduction of an alkali metal or alkaline earth metal compound with a reductant, resulting in an improvement in electron injection efficiency to the light-emitting layer.

According to this electroluminescence device, the reduction, which can be the reaction of the alkali metal or alkaline earth metal compound with the reductant to form the reduced layer, produces an elemental alkali metal or alkaline earth metal having a low work function during the manufacture. This product metal immediately travels to the light-emitting layer. Then, the top of the light-emitting layer is doped with the product metal, which serves as a dopant to deliver the ability to inject electrons into the top of the light-emitting layer. Thus, the reduced layer provides an improvement in the electron injection efficiency to the light-emitting layer.

In this electroluminescent device, the reductant is preferably aluminum. Aluminum is relatively stable and has good conductivity. Therefore, the unreacted residue of aluminum contained in the reduced layer after the reduction is not readily oxidized during the formation of the transparent conductive film. Thus, this residue does not decrease the conductivity. In addition, the residual aluminum can also function as an electrode together with the transparent conductive film.

In this electroluminescent device, the reduced layer preferably has a visible light transmittance exceeding 50%. More unreacted reductant remaining in the reduced layer leads to more impairment in the transparency (transmittance) of the reduced layer. Conversely, less unreacted reductant remaining in the reduced layer leads to less impairment in the transparency (transmittance) of the reduced layer. Therefore, the reduced layer is preferably formed such that it has a visible light transmittance exceeding 50%. Such a reduced layer exhibits better transparency, which increases the emission intensity of the device. In addition, such a reduced layer also contains little reductant oxide generated by the reaction of the unreacted reductant with oxygen during the deposition of the transparent conductive film. As a result, the reduced layer can prevent the reductant oxide from decreasing the conductivity, thus providing excellent emission characteristics.

A method for manufacturing an electroluminescent device according to the present invention can include the steps of forming an electrode on a substrate, forming a hole-injection layer on the electrode, forming an organic light-emitting layer on the hole-injection layer, forming an alkali metal or alkaline earth metal compound layer on the light-emitting layer, depositing a reductant on the alkali metal or alkaline earth metal compound layer to form a reduced layer through the reduction of the alkali metal or alkaline earth metal compound layer with the reductant, and forming a transparent conductive film on the reduced layer.

According to this manufacturing method, the reduction, which is the reaction of the alkali metal or alkaline earth metal compound layer with the reductant to form the reduced layer, produces an elemental alkali metal or alkaline earth metal having a low work function. This product metal immediately travels to the light-emitting layer. Then, the top of the light-emitting layer is doped with the product metal, which serves as a dopant to deliver the ability to inject electrons into the top of the light-emitting layer. Thus, the reduced layer provides an improvement in the electron injection efficiency to the light-emitting layer.

In this manufacturing method, the reductant is preferably aluminum. Aluminum is, as described above, relatively stable and has good conductivity. Therefore, the unreacted residue of aluminum contained in the reduced layer after the reduction is not readily oxidized during the formation of the transparent conductive film. Thus, this residue does not decrease the conductivity. In addition, the residual aluminum can also function as an electrode together with the transparent conductive film.

In this manufacturing method, the alkali metal or alkaline earth metal compound layer preferably has a thickness in the range of 0.5 to 10 nm. The alkali metal or alkaline earth metal compound layer, if having a thickness of 0.5 mm or more, can produce a sufficient amount of the product metal through the reduction with the reductant. Such a sufficient amount of the product metal can serve as a dopant to deliver high ability to inject electrons into the light-emitting layer. Meanwhile, if the thickness of the alkali metal or alkaline earth metal compound layer is 10 nm or less, the product metal can more reliably travel to the light-emitting layer to serve as a dopant. Therefore, such an alkali metal or alkaline earth metal compound layer can more reliably prevent the residue of the product metal from decreasing the conductivity of the reduced layer by the reaction with oxygen during the formation of the transparent conductive film.

### BRIEF DESCRIPTION OF THE DRAWINGS

The invention will be described with reference to the accompanying drawings, wherein like numerals reference like elements, and wherein:

FIG. 1 is a schematic sectional view of an organic EL device of the present invention; and

FIGS. 2(a), 2(b), and 2(c) are sectional views for illustrating a method for manufacturing an organic EL device according to the present invention.

### DETAILED DESCRIPTION OF PREFERRED EMBODIMENTS

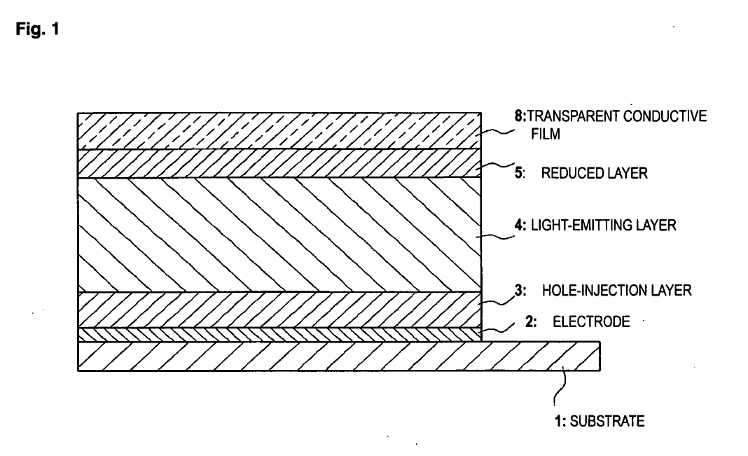

A top-emitting organic EL device according to an embodiment of the present invention will now be described. FIG. 1 is a schematic sectional view of this organic EL device.

In case of a top-emitting organic EL device, a substrate 1 is, for example, an opaque, semiconductor or insulating substrate (a transparent glass substrate is used for a transparent organic EL device that emits light from both surfaces).

An electrode 2 is formed on a surface of the substrate 1. Examples of the material for the electrode 2 include metals, such as aluminum, silver, and copper and transparent conductive materials (especially for transparent organic EL devices).

A hole-injection layer 3 can be formed to inject holes supplied by the electrode 2 efficiently into a light-emitting layer 4, that is, an organic EL layer. The hole-injection layer 3, therefore, is composed of a material having a high work function relative to the vacuum level, for example, a triphenylamine derivative film having a thickness of 50 to 100 nm.

The light-emitting layer 4, which is an organic thin-film layer, is exemplified by a distyrylbiphenyl derivative film having a thickness of approximately 50 nm. A reduced layer 5 is formed by the reduction of a metal compound layer with a reducing metal functioning as a reductant to result in an improvement in electron injection efficiency to the light-emitting layer 4, as will be described in greater detail below.

A transparent conductive film 8 is an ITO transparent conductive film for use in, for example, wiring. This transparent conductive film 8 has a thickness of approximately 100 nm.

As described above, the organic EL device includes a reduced layer 5. The metal compound layer for forming the reduced layer 5 contains one or more compounds of metals with low work functions (alkali metals, such as lithium, sodium, potassium, rubidium, and cesium; alkaline earth metals, such as calcium, strontium, and barium; beryllium; and magnesium). Such metal compounds can provide high electron injection efficiency. Examples of such metal compounds include lithium oxide (Li₂O), sodium oxide (Na₂O), rubidium oxide (Rb₂O), cesium oxide (Cs₂O), lithium fluoride (LiF), sodium fluoride (NaF), rubidium fluoride (RbF), cesium fluoride (CsF), magnesium oxide (MgO), calcium oxide (CaO), magnesium fluoride (MgF₂), and calcium fluoride (CaF₂). This metal compound layer may contain one of these materials or a mixture of these materials at any mixing ratio.

The reducing metal functioning as a reductant is not particularly limited. It should b understood that the reducing metal may be any metal that can reduce the metal compound layer. Examples of the reducing metal include aluminum, sodium, calcium, magnesium, and cerium, among which aluminum is particularly preferred. As will be described in greater detail below, the deposition of the reducing metal, such as aluminum, onto the metal compound layer, such as an alkali metal compound layer, by, for example, evaporation causes evaporated atoms of the reducing metal to reduce the metal compound layer. This reduction produces alkali metal atoms, which have a work function low enough to serve as an electron-injection layer (O plus E, Vol. 22, No. 11, P. 1416, 2000).

For example, if the metal compound for the metal compound layer is lithium fluoride (LiF) and the reducing metal used is aluminum, the reduced layer 5 is formed by the following reduction of the metal compound:

3LiF+Al→3Li+AlF₃

The product lithium travels to the light-emitting layer 4. Then, the top of the light-emitting layer 4 is doped with the lithium, which serves as a dopant to deliver the ability to inject electrons into the light-emitting layer 4. Thus, the reduced layer 5 results in an improvement in the electron injection efficiency to the light-emitting layer 4.

After the doping of the light-emitting layer 4 with the product metal to deliver the ability to inject electrons, the major component of the reduced layer 5 changes to the other product of the reduction, that is, a reducing metal compound (AlF₃ for this example). The reduced layer 5 also contains minor components such as unreacted reducing metal, unreacted alkali metal or alkaline earth metal, and the product metal, which is the residue that failed to travel to the light-emitting layer 4.

The thicknesses of the metal compound layer and the reducing metal (reductant) are not particularly limited. Preferably, they have such a molar ratio as to react just enough stoichiometrically and, therefore, as to leave no minor components. If the metal compound layer has an excessively large thickness, the product alkali or alkali earth metal incompletely travels to the light-emitting layer 4 even though the metal compound layer is completely reduced. As a result, a large amount of the product metal remains in the reduced layer 5. Then, the transparent conductive film 8 is deposited on the reduced layer 5, in which the residue of the product alkali or alkali earth metal contained reacts with oxygen, leading to a decrease in the conductivity of the reduced layer 5. Therefore, the metal compound layer preferably has a predetermined thickness or less, irrespective of the thickness of the reducing metal deposited on the metal compound layer. Specifically, the metal compound layer preferably has a thickness of 10 nm or less, as will be described later.

If the organic EL device is manufactured as a transparent organic EL device that emits light from both surfaces, the electrode 2 may be composed of ITO or SnO₂ and the substrate 1 may be composed of transparent glass or a transparent polymeric film, such as polyester, to attain transparency.

An embodiment of a method for manufacturing the organic EL device in FIG. 1 will now be described. The electrode 2 is deposited on the substrate 1, which is an insulating film, by sputtering. This electrode 2 has a thickness of 100 nm and is composed of, for example, copper.

The hole-injection layer 3 is deposited on the electrode 2 by vacuum evaporation. This hole-injection layer 3 has a thickness of 60 nm and is composed of triphenyldiamine.

The light-emitting layer 4 is formed on the hole-injection layer 3. This light-emitting layer 4 has a thickness of 40 nm and is composed of distyrylbiphenyl.

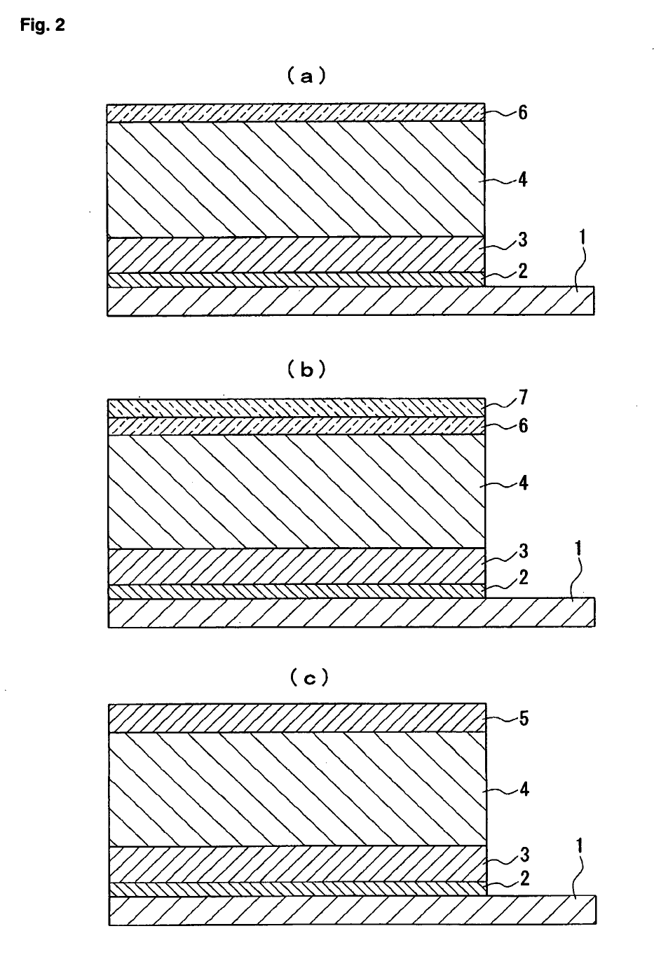

Referring to FIG. 2(a), a metal compound layer 6 for forming the reduced layer 5 can be deposited on the light-emitting layer 4 in a vacuum of about 10⁻⁶ Torr by vacuum evaporation. This metal compound layer 6 is, for example, a LiF film having a thickness of 5 nm.

Referring then to FIG. 2(b), a reducing metal layer 7 is deposited on the metal compound layer 6 composed of LiF in a vacuum of about 10⁻⁶ Torr by vacuum evaporation in the same way as the metal compound layer 6. This reducing metal layer 7 is an aluminum film having a thickness of 5 nm.

Aluminum, as described above, reduces LiF to produce lithium atoms, which travel to the light-emitting layer 4. Then, the top of the light-emitting layer 4 is doped with lithium, which serves as a dopant to deliver the ability to inject electrons into the top of the light-emitting layer 4. In addition, this reaction transforms the metal compound layer 6 and the reducing metal layer 7 into a single layer mainly containing a reducing metal compound. This layer is the reduced layer 5, as shown in FIG. 2(c). Thus, the reduced layer 5 provides an improvement in the electron injection efficiency to the light-emitting layer 4. The reducing metal layer 7 does not react with oxygen because the reducing metal layer 7 is deposited on the metal compound layer 6 in a high vacuum with no oxygen.

The metal compound layer 6 preferably has a thickness of 0.5 to 10 nm. If its thickness is less than 0.5 nm, the reduction of the metal compound layer 6 with the reducing metal (reductant) produces an insufficient amount of alkali or alkali earth metal. Such metal serves as a dopant only to provide an unsatisfactory improvement in the electron injection efficiency. Meanwhile, if its thickness is more than 10 nm, as described above, the product alkali or alkali earth metal travels incompletely to the light-emitting layer 4. The residue of the product metal may bring about a decrease in the conductivity of the reduced layer 5.

The reduced layer 5 preferably has a transmittance exceeding 50% to visible light, specifically, to light with a wavelength of 550 nm.

Little unreacted reducing metal (reductant) remaining in the reduced layer 5 does not impair the transparency (transmittance) of the reduced layer 5. If the reducing metal layer 7 has the proper thickness, corresponding to that of the metal compound layer 6, the reduced layer 5 containing little unreacted reducing metal (reductant) can be formed. Such a reduced layer 5 exhibits a visible light transmittance exceeding 50%, leading to an increase in the emission intensity of the device. In addition, the reduced layer 5 also contains little reductant oxide generated by the reaction of the unreacted reductant with oxygen during the deposition of the transparent conductive film 8. The reduced layer 5, therefore, can prevent the reductant oxide from decreasing the conductivity, thus providing excellent emission characteristics.

Subsequently, the transparent conductive film 8, which is an ITO film having a thickness of 150 nm, is deposited on the reduced layer 5 by sputtering to complete the organic EL device in FIG. 1.

This organic EL device has excellent emission characteristics because the reduced layer 5 has a function to provide an improvement in the electron injection efficiency to the light-emitting layer 4.

In addition, the reducing metal (reductant) is oxidized through the reduction of the metal compound layer 6 composed of alkali or alkali earth metal. This reducing metal, therefore, is no longer oxidized during the subsequent process, preventing a decrease in the transmittance of the reduced layer 5.

Furthermore, the organic EL device can achieve a transmittance of 80% to light emitted by the light-emitting layer 4. That is, if the light-emitting layer 4 is a 40-nm-thick distyrylbiphenyl film, the hole-injection layer 3 is a 60-nm-thick triphenyldiamine film, and the material for the metal compound layer 6 is a 5-nm-thick LiF film, then the resultant organic EL device can have an emission intensity of 10,000 cd/m². For example, organic EL devices having an emission intensity of 100 cd/m² can be practically used in cell phones. Therefore, the organic EL device of the present invention can provide sufficient emission intensity as a top-emitting device. Thus, the present invention can provide an easy method for manufacturing an integrated multifunctional semiconductor device including a single insulating substrate provided with additional electronic circuitry.

Evaluations of four types of experimental organic EL devices will now be described. These organic EL devices did not include the transparent conductive film 8. Instead, the reducing metal layer 7 was made to serve also as an electrode (the transparent conductive film 8). This reducing metal layer 7 was a vapor-deposited aluminum film having a thickness of 200 nm. The metal compound layers 6 of these four types of devices were LiF films having thicknesses of 0.5 nm, 1 nm, 3 nm, and 5 nm, respectively. The electrode 2 of each device was an ITO film having a thickness of 100 nm. The substrate 1 of each device was polished glass having a thickness of 1 mm. The hole-injection layer 3 and the light-emitting layer 4 were the same as those in the embodiment described above.

The emission intensities of these four types of organic EL devices were measured to be 5,000 cd/m² for the 0.5-nm-thick LiF film, 8,000 cd/m² for the 1-nm-thick LiF film, 3,000 cd/m² for the 3-nm-thick LiF film, and 1,000 cd/m² for the 5-nm-thick LiF film.

The reducing metal layer 7, if made of a 5-nm-thick aluminum film, exhibits a transmittance of 80%. Therefore, the above results demonstrate that these devices, having the top-emitting structure, can achieve practical emission intensity.

Additional five types of organic EL devices were manufactured that included LiF films having thicknesses of 2 nm, 4 nm, 6 nm, 10 nm, and 12 nm, respectively, as the metal compound layers 6. The other structure of these devices was the same as those in Example 1.

The emission efficiencies (maximum efficiencies) of these five types of organic EL devices were measured to be 9.21 m/W for the 2-nm-thick LiF film, 6.41 m/W for the 4-nm-thick LiF film, 4.41 m/W for the 6-nm-thick LiF film, 3.71 m/W for the 10-nm-thick LiF film, and an undetectable level for the 12-nm-thick LiF film.

These results show that the metal compound layer 6, if having a thickness exceeding 10 nm, does not exhibit the effect of improving the electron injection efficiency after the reduction. Therefore, these results confirmed that the thickness of the metal compound layer 6 is preferably 10 nm or less.

One embodiment of the present invention has been described above in detail with reference to the drawings. However, it should be understood that specific structures of organic EL devices of the present invention are not limited to the above embodiment. A variety of modifications are permitted within the spirit and scope of the present invention.

What is claimed is:

1. An electroluminescent device, comprising:
a substrate;
an electrode disposed on the substrate;
a hole-injection layer disposed on the electrode;
a light-emitting layer disposed on the hole-injection layer;
a reduced layer disposed on the light-emitting layer, the reduced layer being formed by a reduction of an alkali metal or alkaline earth metal compound with a reductant; and
a transparent conductive film disposed on the reduced layer,
the reduced layer providing an improvement in electron injection efficiency to the light-emitting layer.

2. The electroluminescent device according to claim 1, the reductant being aluminum.

3. The electroluminescent device according to claim 1, the reduced layer having a visible light transmittance exceeding 50%.

4. A method for manufacturing an electroluminescent device, comprising:
forming an electrode on a substrate;
forming a hole-injection layer on the electrode;
forming an organic light-emitting layer on the hole-injection layer;
forming an alkali metal or alkaline earth metal compound layer on the light-emitting layer;
depositing a reductant on the alkali metal or alkaline earth metal compound layer, the alkali metal or alkaline earth metal compound layer being reduced with the reductant to form a reduced layer; and
forming a transparent conductive film on the reduced layer.

5. The method for manufacturing an electroluminescent device according to claim 4, the reductant being aluminum.

6. The method for manufacturing an electroluminescent device according to claim 4, the alkali metal or alkaline earth metal compound layer having a thickness in a range of 0.5 to 10 nm.
